(19) United States
(12) Patent Application Publication
(10) Pub. No.: US 2026/0020152 A1
(43) Pub. Date: Jan. 15, 2026

(54) POWER MODULE, INVERTER HAVING A POWER MODULE

(71) Applicant: SCHAEFFLER TECHNOLOGIES AG & CO. KG, Herzogenaurach (DE)

(72) Inventor: Alexander Kuschel, Regensburg (DE)

(73) Assignee: Vitesco Technologies GmbH, Regensburg (DE)

(21) Appl. No.: 18/869,245

(22) PCT Filed: May 24, 2023
(86) PCT No.: PCT/EP2023/063943

§ 371 Date: Sep. 28, 2025

(30) Foreign Application Priority Data
May 31, 2022 (DE) 10 2022 205 510.1

(51) Int. Cl. H05K 1/11; H02M 7/00; H05K 1/18

(52) U.S. Cl. CPC H05K 1/11; H02M 7/003; H05K 1/181; H05K 2201/10015; H05K 2201/10166

(57) ABSTRACT

A power module, having a circuit carrier having an upper side on which a first electrical connection surface for the surface mounting of first transistor switches and a second electrical connection surface for the surface mounting of second transistor switches and also third electrical connection surfaces are formed. The first and the second connection surfaces are electrically insulated from one another extend along a direction of extent of the circuit carrier, and the third connection surfaces are electrically insulated from one another and from the first and the second connection surfaces and are arranged in the direction of extent next to one another and between the first and the second connection surfaces. Snubber circuits are formed at least partially on one of a plurality of regions of the circuit carrier in each case, such that the regions span one of the third connection surfaces and the second connection surface.

### CROSS-REFERENCE TO RELATED APPLICATIONS

This application claims priority to PCT Application PCT/EP2023/063943, filed May 24, 2023, which claims priority to German Patent Application No. DE 10 2022 205 510.1, filed May 31, 2022. The disclosures of the above applications are incorporated herein by reference.

### FIELD OF THE INVENTION

The present invention relates to a power module and an inverter having an aforementioned power module.

### BACKGROUND OF THE INVENTION

Power modules having transistor switches for converting currents or voltages and inverters having power modules, for example for providing phase currents for an electric machine, are known and are used inter alia in drive systems of electrically driven motor vehicles.

There is here the general demand to configure the power modules to be more powerful and have lower power losses at the same time.

### SUMMARY OF THE INVENTION

Accordingly, the object of the present application is to provide a powerful and, at the same time, low-loss power module.

This object is achieved by subjects described. Other embodiments are the subject matter also described.

According to a first aspect of the invention, a power module is provided for converting currents or voltages, for use in an inverter for providing phase currents for an electric machine of an electrically driven motor vehicle.

The power module has a circuit carrier, for example in the form of a printed circuit board or a ceramic substrate or another known comparable circuit carrier, which has a first electrical connection surface for the surface mounting of first transistor switches and a second electrical connection surface for the surface mounting of second transistor switches and also a plurality of third electrical connection surfaces.

In this case, the first and the second connection surface and also the third connection surfaces are realized or arranged to be electrically insulated from one another on the same side of the circuit carrier. The first and the second connection surface respectively extend along a direction of extent of the circuit carrier in each case. The third connection surfaces are electrically insulated from one another (and from the first and the second connection surface) and realized or arranged in the direction of extent next to one another and between the first and the second connection surface.

The above-described connection surfaces are in each case continuous electrically conductive surfaces made from a metal or a metal alloy, such as e.g. copper or a copper alloy. In this case, depending on the field of application of the power module, the connection surfaces are realized for conducting currents of up to several hundred amperes, with a corresponding layer thickness and surface width of the respective connection surfaces. Depending on the power requirement of the power module, the connection surfaces are realized in a correspondingly flat extended manner for the parallel connection of a plurality of transistor switches.

The power module further has a plurality of snubber circuits or snubber elements, for example in the form of RC elements, which are in each case formed at least partially on one of a plurality of (sub)regions of the upper side of the circuit carrier in each case, wherein the regions in each case partially span one of the third connection surfaces and the second connection surface. Here, the regions in each case partially overlap with the respective corresponding third connection surface and the second connection surface. The regions are in each case composed of an edge region of the third connection surface, which edge region adjoins the second connection surface, an edge region of the second connection surface, which edge region adjoins the third connection surface, and possibly an intermediate region which reaches from the second to the third connection surface. The edge regions are in particular only a proportion of the area of the underlying region, for example not more than 50%, 30%, 20% or 10%. The intermediate region contains an electrically isolating structure that electrically insulates the two connection surfaces, for example a trench between the connection surfaces. What are termed “electrically insulated” here are conductive features which may have different potentials. An electrically insulated conductor track section may further be in the intermediate region, which is used as a connecting element in a snubber circuit. The snubber circuit is therefore located in each case in a region at which the second connection surface and the third connection surfaces adjoin one another and in a region between the circuit carrier on one side and a second or a third busbar on the other side.

The snubber circuits here include both circuit components of the snubber elements, such as e.g. capacitors and resistors (in the case of RC elements) and (internal) electrical connections between these circuit components, such as e.g. conductor tracks, which are formed on the circuit carrier, and also (external) electrical connections of the respective snubber elements to respective corresponding (external) circuit components of the power module, such as e.g. conductor tracks which are formed on the circuit carrier, or bond connections which are bonded to the corresponding components. The snubber circuits are in each case electrically connected by these external electrical connections to the respective corresponding third connection surface and the second connection surface. The circuit components and the internal or external electrical connections of the respective snubber elements are at least partially, and may be completely realized or arranged on in each case one of the plurality of regions of the upper side of the circuit carrier, wherein each individual region in each case partially spans one of the third connection surfaces and the second connection surface and thus electrically connects these two connection surfaces via the shortest connection path.

For functional reasons, the power modules generate high-frequency oscillations in currents with voltage peaks during operation, which may occur during the switching of inductive loads, such as e.g. electric machines, and may lead to malfunctions and even to the failure of the power modules or other circuits which are electrically connected to the power modules. These high-frequency oscillations prevent the power module from switching the transistor switches faster and thus operating the power module at high power with a low power loss.

The source of the high-frequency oscillations in currents with voltage peaks is due to the transistor switches which are switched on/off in a clocked manner during operation of the power module and is therefore located in the (closed) circuit between the positive-voltage-side and the negative-voltage-side supply current connections of the power module to the respective transistor switches. In the above-described power module, the two supply current connections are in each case formed by the second connection surface or the third connection surfaces on the same upper side of the circuit carrier. If the power module is part of an inverter, then the first connection surface is formed as a phase current connection of the power module.

By arranging or electrically connecting the snubber circuits as damping elements directly on the respective regions of the same upper side of the circuit carrier (such as the second connection surface or the third connection surfaces) which partially span the second connection surface and the respective corresponding third connection surfaces and thus the two supply current connections (to the transistor switches), the snubber circuits are placed and electrically connected directly and in a low-inductive manner at the source of the high frequency oscillations. As a result, the snubber circuits efficiently damp the high-frequency oscillations directly at their source before these oscillations propagate via the supply current connections to other circuit components of the power module and further circuit apparatuses connected to the power module and may cause faults or other damage there. Due to the small distance from the snubber circuits to the source of the high-frequency oscillations, the efficiency of the snubber circuits is thus maximized. Accordingly, the transistor switches are switched fast and with little loss with a high switching speed. Consequently, a power module may be operated with a high power and, at the same time, with little loss. In addition, this makes it possible for the power module to use fast-switching and low-loss transistor switches.

The above-described power module may be used in (power) inverters, (power) DC-to-DC voltage converters, (power) converters or comparable (power) electronics devices, where a high switching speed with a simultaneously low power loss at the transistor switches is demanded.

For example, the snubber circuits in each case have a capacitor and/or a resistor, wherein the capacitor and/or the resistor of the respective snubber circuits are in each case arranged on the respective corresponding region.

For example, the snubber circuits in each case have (at least) one bond connection, wherein the bond connection of the respective snubber circuits in each case spans the respective corresponding region (at least partially).

For example, the snubber circuits in each case have at least one conductor track connection (or conductor track sections) which are formed on the same upper side of the circuit carrier on which the above-mentioned connection surfaces are formed. Here, the conductor track connections are electrically insulated or isolated from the above-mentioned connection surfaces.

Using the above-mentioned capacitors, resistors, bond connections and/or conductor track sections, the snubber circuits are easily and cost-effectively realized (exclusively) using standard components with many different designs. In addition, the snubber circuits are adapted to various requirements, such as e.g. different power requirements, in a simple manner.

For example, the first connection surface and/or the second connection surface and/or the third connection surfaces are realized as conductor tracks that are formed on the same side of the circuit carrier.

For example, the first connection surface has first connection sections which extend transversely to the direction of extent and in the direction of the second connection surface. Here, the first connection sections and the third connection surfaces alternate in the direction of extent or are arranged alternately to one another. Alternatively or in addition to this, the second connection surface for example has second connection sections which extend transversely to the direction of extent and in the direction of the first connection surface. In this case, the second connection sections and the third connection surfaces alternate in the direction of extent or are arranged alternately to one another.

The power module for example has a plurality of first transistor switches which are surface-mounted on the first connection surface and are in each case electrically connected by a bond connection to a respective corresponding third connection surface. Here, one, two or more first transistor switches may be electrically connected to the same corresponding third connection surface.

The power module for example further has a plurality of second transistor switches which are surface-mounted on the second connection surface and are in each case electrically connected by a bond connection to the first connection surface.

The first transistor switches and/or the second transistor switches are for example formed as silicon carbide transistor switches.

As the snubber circuits may, due to their arrangement directly at the source of the high-frequency oscillations, efficiently damp the high-frequency oscillations directly at the source and therefore effectively prevent the consequential damage due to them, these snubber circuits enable a fast and low-loss switching of the transistor switches. Accordingly, fast-switching and low-loss silicon carbide transistor switches may be used in the power module.

The power module for example further has a first busbar which (is for example shaped in a comb-shaped manner and) has first connecting lugs or connecting tabs (or connecting legs), by which the first busbar rests on the first connection surface and is electrically connected to the first connection surface. Alternatively or in addition to the first busbar, the power module has a second busbar which (is for example likewise shaped in a comb-shaped manner and) has second connecting lugs or connecting tabs (or connecting legs), by which the second busbar rests on the second connection surface and is electrically connected to the second connection surface. Alternatively or in addition to the first or the second busbar, the power module has a third busbar which (is for example likewise shaped in a comb-shaped manner and) has third connecting lugs or connecting tabs (or connecting legs), by which the third busbar rests on the respective third connection surfaces and is electrically connected to the respective third connection surfaces.

In the event that the power module has the second and the third busbar, the second and the third busbar (except for the respective first connecting lugs or the respective second connecting lugs) are for example arranged such that they substantially overlap with one another.

For example, the second and/or the third connecting lugs in each case run at least partially across one of the regions which in each case partially span one of the third connection surfaces and the second connection surface.

For example, the second and/or the third connecting lugs are in each case shaped in such a manner that an (intermediate) space is located or forms in each case between the respective second or the respective third connecting lugs on the one hand and the respective corresponding regions—across which the respective second or the respective third connecting lugs run—on the other hand. In each case, one of the snubber circuits is at least partially arranged or placed in one of these spaces in each case.

The intermediate spaces allow a compact design of the snubber circuits that saves installation space without requiring additional installation spaces which could lead to larger dimensioning of the structural volume of the power module, increasing the overall height of the power module.

For example, the first connection surface and the second connection surface in each case extend along the direction of extent from a first end region of the circuit carrier up to a second end region of the circuit carrier, which faces away from the first end region in the direction of extent. Here, the first connection surface and the second connection surface extend parallel to one another.

For example, the circuit carrier has two outer strip sections, which face away from one another, and a central strip section between the two outer strip sections. Here, the strip sections extend for example along the direction of extent from the first end region of the circuit carrier up to the second end region of the circuit carrier. Furthermore, the first and the second connection surfaces are in each case for example formed in a distributed manner on each of the two outer strip sections, wherein the third connection surfaces are formed for example on the central strip section.

For example, the first or the second connection sections—depending on which of the connection sections has the power module—are likewise formed on the central strip section.

For example, the first connection surface and the second connection surface and the third connection surfaces and also the above-mentioned regions are located on the same surface of the circuit carrier or are formed on the same surface of the circuit carrier.

According to a second aspect of the invention, an inverter is provided for providing phase currents for an electric machine of an electrically driven motor vehicle.

The inverter has at least one previously described power module, for providing phase currents for an electric machine, and a driver circuit for operating the power module, and also a housing, wherein the power module and the driver circuit are arranged in the housing and electrically connected to one another.

The second connection surface on the one hand and the third connection surfaces on the other hand are supply potential connections (for DC voltage). The first connection surface is a load connection surface. In populated power modules, the first transistor switches are connected to one another in parallel, wherein the second transistor switches are also connected to one another in parallel. The first transistors are parallel connected by the third busbar or parallel connected by the connection to the same third connection surface. The first transistors and the second transistors in each case form a half bridge in pairs. The first transistors form a low-side switching element of the half bridge in each case and the second transistors form a high-side switching element of the half bridge in each case. The connecting point inside the half bridge (i.e. the connection between the first transistors on the one hand and the second transistors on the other hand) corresponds to the first connection surface. The snubber circuits are located in a region at which the second connection surface, which corresponds to a first supply potential (connection), adjoins the third connection surfaces, which correspond to a second supply potential (connection). The connection of the snubber circuits to the supply potentials therefore requires only very short lines. The connection of the supply potentials (by using busbars) may take place from one side, while the opposite side is used for connecting the connecting point (phase or load connection), for example by a further busbar, and thus couples less with the supply potentials. The snubber circuits may be arranged between the busbars of the supply potentials and the circuit carrier.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Exemplary embodiments of the invention are explained in more detail below with reference to the appended drawings. In the figures:

FIG. 1 shows parts of a power module according to an exemplary embodiment of the invention in a first schematic plan view;

FIG. 2 shows a snubber circuit of the power module from FIG. 1 in a second schematic plan view;

FIGS. 3A, 3B show further components of the power module from FIG. 1 in two further schematic plan views; and

FIG. 4 shows a side view of a subsection of the power module from FIG. 1 in a schematic cross-sectional illustration.

### DETAILED DESCRIPTION OF THE PREFERRED EMBODIMENTS

The following description of the preferred embodiment(s) is merely exemplary in nature and is in no way intended to limit the invention, its application, or uses.

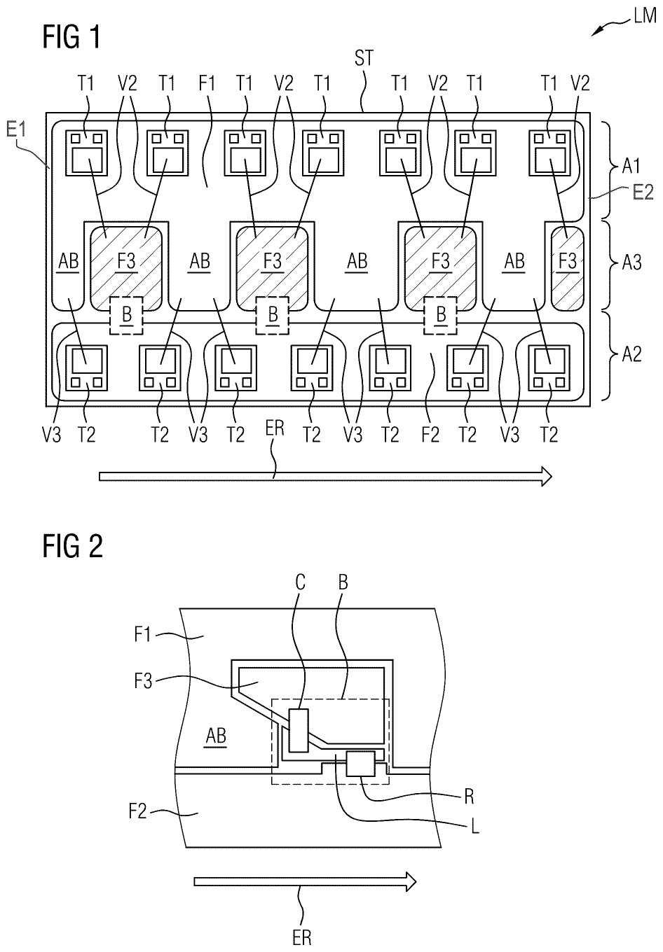

FIG. 1 shows parts of a power module LM according to an exemplary embodiment of the invention in a first schematic plan view.

The power module LM is in this embodiment formed as a half-bridge module of an inverter for providing phase currents for an electric machine.

The power module LM has a circuit carrier ST in the form of a ceramic substrate which has on its upper side a first electrical connection surface F1, a second electrical connection surface F2, and also a plurality of third electrical connection surfaces F3. Here, the connection surfaces F1, F2, F3 are formed as conductor tracks on the same upper side of the circuit carrier ST, which are electrically insulated or isolated from one another. The first and the second connection surfaces F1, F2 are located on two outer strip sections A1, A2 of the circuit carrier ST, which face away from one another and in each case extend along a direction of extent ER of the circuit carrier ST.

The first connection surface F1 has a plurality of wide connection sections AB which extend parallel to one another and in a prong-shaped (or comb-shaped) manner transversely to the direction of extent ER and in the direction of the second connection surface F2 and thus on a central strip section A3 of the circuit carrier ST between the two outer strip sections A1, A2. The third connection surfaces F3 are formed on the central strip section A3 and thus between the first and the second connection surfaces F1, F2. In this case, the third connection surfaces F3 and the connection sections AB alternate in the direction of extent ER. The third connection surfaces F3 are electrically insulated from one another and from the first and the second connection surfaces F1, F2 and thus also from the connection sections AB of the first connection surface F1.

In this case, the strip sections A1, A2, A3 extend parallel to one another and along the direction of extent ER from a first end region E1 of the circuit carrier ST up to a second end region E2 of the circuit carrier ST, which faces away from the first end region E1.

Accordingly, the first connection surface F1 and the second connection surface F2 also extend in each case along the direction of extent ER from the first end region E1 up to the second end region E2 of the circuit carrier ST and parallel to one another.

Here, the first connection surface F1 and the second connection surface F2 and the third connection surfaces F3 and also the regions B are located on the same surface of the circuit carrier ST and thus on the same plane.

The power module LM further has a group of first transistor switches T1 which are placed one behind the other in the direction of extent ER, surface-mounted on the first connection surface F1 and thus electrically connected on both sides to the first connection surface F1. The first transistor switches T1 are further electrically connected in each case by a bond connection V2 to one of the third connection surfaces F3 in each case. The power module LM further has a group of second transistor switches T2 which are placed one behind the other in the direction of extent ER, surface-mounted on the second connection surface F2 and thus electrically connected on both sides to the second connection surface F2. The second transistor switches T2 are further electrically connected in each case by a further bond connection V3 to one corresponding connection section AB of the first connection surface F1 in each case and thus to the first connection surface F1. The first and the second transistor switches T1, T2 are formed in this embodiment as fast-switching SiC transistors (SiC: “silicon carbide”).

The power module LM further has a group of snubber circuits or snubber elements which are in each case formed at least partially on one of a plurality of regions B of the circuit carrier ST in each case. Here, the regions B are located on the same surface of the circuit carrier ST as the previously mentioned connection surfaces F1, F2, F3 and partially span in each case one of the third connection surfaces F3 and the second connection surface F2. The snubber circuits are in each case electrically connected to the respective corresponding third connection surface F3 and the second connection surface F2.

FIG. 2 shows an exemplary embodiment of the snubber circuit of the power module LM from FIG. 1 in a second schematic plan view.

In FIG. 2, only one of the above-mentioned snubber circuits is depicted by way of example. The snubber circuit has a conductor track section L, a capacitor C and a resistor R, which are arranged in the corresponding region B. Here, the conductor track section L is located between two adjacent connection sections AB of the first connection surface F1, as viewed in the direction of extent ER, and between the corresponding third connection surface F3 and the second connection surface F2, as viewed in the direction transverse to the direction of extent ER. The conductor track section L is electrically insulated or isolated from all of the two adjacent connection sections AB, the corresponding third connection surface F3 and the second connection surface F2. The capacitor C is located partly on the corresponding third connection surface F3 and partly on the conductor track section L and electrically connected to the corresponding third connection surface F3 and the conductor track section L. Therefore, the capacitor C partially spans the corresponding third connection surface F3 and the conductor track section L. The resistor R is located partly on the conductor track section L and partly on the second connection surface F2 and electrically connected to the conductor track section L and the second connection surface F2. Therefore, the resistor R partially spans the conductor track section L and the second connection surface F2. Therefore, the snubber circuit connects the respective corresponding third connection surface F3 to the second connection surface F2 and is configured to reduce high-frequency current components in the direct current of the power module LM which flows during operation of the power module LM between the third connection surfaces F3 on the one hand and the second connection surface F2 on the other hand, and to limit voltage peaks in the direct current.

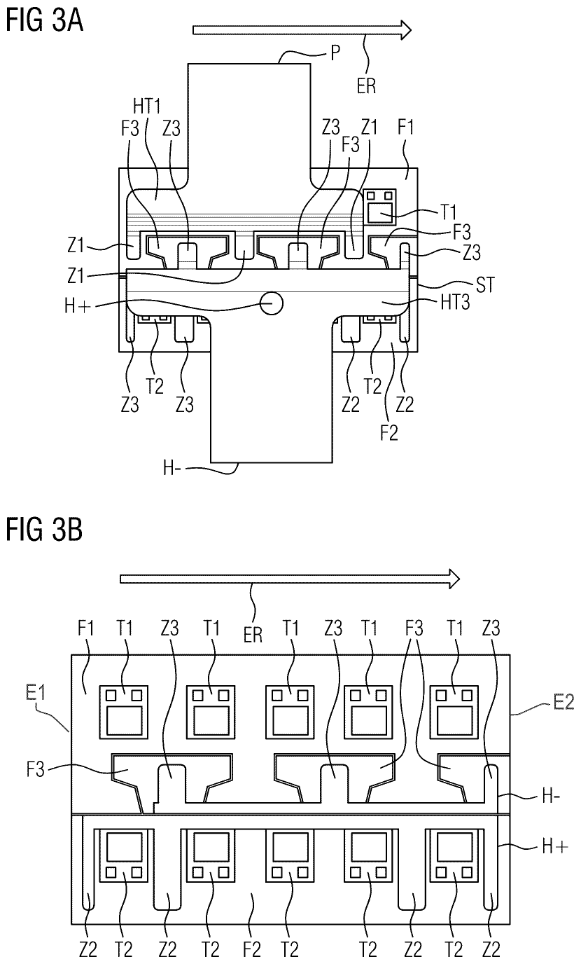

FIGS. 3A, 3B in each case show the previously described power module LM in a further schematic plan view with further circuit components: busbars made from a metal or a metal alloy, such as from copper or a copper alloy, which in each case form a phase current connection (first busbar P), a positive-voltage-side supply current connection (second busbar H+) or a negative-voltage-side supply current connection (third busbar H−) of the power module LM.

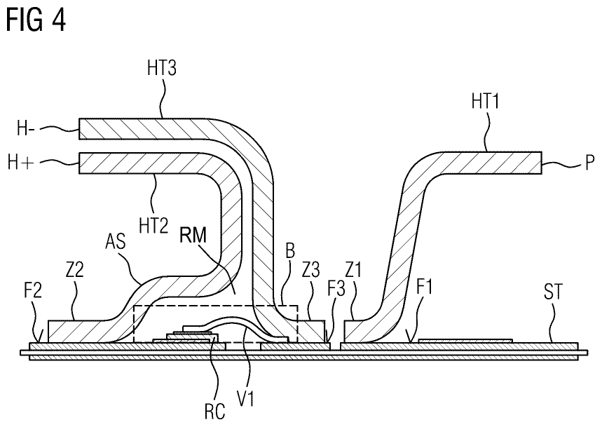

The three busbars P, H+, H− are shaped in a substantially rake- or comb-shaped manner and in each case have a main part HT1, HT2 (see FIG. 4), HT3 that is shaped in a flat extended manner, and connecting lugs (or connecting tabs or connecting legs) Z1, Z2, Z3 that are shaped on the respective main part HT1, HT2, HT3 in a prong-shaped (or comb-shaped) manner.

Here, the first busbar P rests by way of its connecting lugs Z1 on the first connection surface F1 and is electrically contacted multiple times with the first connection surface F1, as is shown in FIG. 3A. The main part HT1 of the first busbar P extends substantially over the first connection surface F1 and parallel to the upper side of the circuit carrier ST.

Analogously, the second busbar H+rests by way of its connecting lugs Z2 on the second connection surface F2 and is electrically contacted multiple times with the second connection surface F2, as is shown in FIG. 3B. The main part HT2 of the second busbar H+ extends substantially over the second connection surface F2 and parallel to the upper side of the circuit carrier ST, as is shown in FIG. 4.

The third busbar H− rests by way of its connecting lugs Z3 on the respective third connection surfaces F3 and is electrically contacted with the respective third connection surfaces F3, as is shown in FIG. 3B. The main part HT3 of the third busbar H− extends likewise substantially over the second connection surface F2 and parallel to the upper side of the circuit carrier ST, as is shown in FIG. 3A. Here, the second and the third busbars H+, H− or their respective main parts HT2, HT3 overlap with one another over the second connection surface F2. The second and the third busbars H+, H− are electrically insulated or isolated from one another for example by an electrical insulation layer, which is arranged between these two busbars H+, H−.

FIG. 4 shows a side view of a subsection of the previously described power module LM in a schematic cross-sectional illustration, in which the side sections of the previously mentioned busbars P, H+, H− are clearly depicted.

The connecting lugs Z1, Z2, Z3 of the respective busbars P, H+, H− are shaped in a substantially S-shaped manner and extend from the respective main parts HT1, HT2, HT3 in the direction of the respective corresponding connection surfaces F1, F2, F3 both physically and electrically connected to the respective corresponding connection surfaces F1, F2, F3, for example by bonding, welding, soldering, sintering or in a similar manner. Here, the connecting lugs Z2, Z3 of the second and the respective third busbars H+, H− run in each case at least partially across in each case one of the previously mentioned regions B on the upper side of the circuit carrier ST. Here, the connecting lugs Z2 of the second busbar H+ are additionally bent at their respective sections AS which face the second connection surface F2, so that these sections AS hang, spaced from the second connection surface F2, over the second connection surface F2 and in each case form a small low-inductive “loop” (low-inductive intermediate circuit). Because of the “loops”, one space RM is formed in each case on the respective region B of the upper side of the circuit carrier ST between the sections AS of the respective connecting lugs Z2 on the one hand and the second connection surface F2 on the other hand.

One of the previously mentioned snubber circuits in each case is arranged in the respective spaces RM in a manner that saves installation space. In the embodiment depicted in FIG. 4, the snubber circuit has a bond connection V1, an RC element RC (as a standard component) having a capacitor and a resistor. Because of the bond connection V1, the snubber circuit or its RC element RC is electrically contacted with the corresponding third connection surface F3. The RC element RC is placed on the second connection surface F2 and electrically contacted with the second connection surface F2. Due to the low-inductive “loops” and the effectively placed snubber circuits, high switching speeds may be realized. The high-frequency oscillations in the currents with voltage peaks, which arise during operation of the power module LM with the fast-switching SiC transistor switches T1, T2, are damped directly by the respective snubber circuits (in the respective regions B) which are connected in a low-inductive manner in direct proximity. Consequential damage due to these oscillations in the power module LM itself or in other circuit components of the inverter is thus efficiently prevented.

The description of the invention is merely exemplary in nature and, thus, variations that do not depart from the gist of the invention are intended to be within the scope of the invention. Such variations are not to be regarded as a departure from the spirit and scope of the invention.

1. (Canceled)

2. (Canceled)

3. (Canceled)

4. (Canceled)

5. (Canceled)

6. (Canceled)

7. (Canceled)

8. (Canceled)

9. (Canceled)

10. (Canceled)

11. (Canceled)

12. (Canceled)

13. (Canceled)

14. (Canceled)

15. (Canceled)

16. (Canceled)

17. (Canceled)

18. (Canceled)

19. A power module, comprising:
a first plurality of transistor switches;
a second plurality of transistor switches;
a circuit carrier, further comprising:
an upper side on which a first electrical connection surface for the surface mounting of the first plurality of transistor switches, and a second electrical connection surface for the surface mounting of the second plurality of transistor switches and a plurality of third electrical connection surfaces are formed;
wherein the first electrical connection surface and the second electrical connection surface are electrically insulated from one another and in each case extend along a direction of extent of the circuit carrier, and the plurality of third electrical connection surfaces are electrically insulated from one another and from the first electrical connection surface and the second electrical connection surface and are arranged in the direction of extent next to one another and between the first electrical connection surface and the second electrical connection surface;
a plurality of snubber circuits which are formed at least partially on one of a plurality of regions of the circuit carrier, and the regions partially span one of the plurality of third electrical connection surfaces and the second electrical connection surface;
wherein the snubber circuits are electrically connected to the respective corresponding one of the plurality of third electrical connection surfaces and the second electrical connection surface.

20. The power module of claim 19, each of plurality of snubber circuits further comprising:
a capacitor;
wherein the capacitor of the respective plurality of snubber circuits are in each case arranged in the respective corresponding region.

21. The power module of claim 19, each of plurality of snubber circuits further comprising:
a resistor;
wherein the resistor of the respective plurality of snubber circuits are in each case arranged in the respective corresponding region.

22. The power module of claim 19, each of plurality of snubber circuits further comprising:
at least one first bond connection,
wherein the at least one first bond connection of each of plurality of snubber circuits snubber circuits in each case at least partially spans the respective corresponding region.

23. The power module of claim 22, further comprising:
a second bond connection, the first plurality of transistor switches, which are surface-mounted on the first electrical connection surface, are in each case electrically connected by means of the second bond connection to one of the plurality of third electrical connection surfaces in each case; and
a third bond connection, the second transistor switches, which are surface-mounted on the second electrical connection surface, are in each case electrically connected by means of the third bond connection to the first electrical connection surface.

24. The power module of one of claim 19, each of plurality of snubber circuits further comprising:
at least one conductor track connection;
wherein the at least one conductor track connection is formed on the upper side of the circuit carrier.

25. The power module of one of claim 19, wherein at least one of the first electrical connection surface and/or the second electrical connection surface and/or the plurality of third electrical connection surfaces are conductor tracks.

26. The power module of claim 19, wherein the first plurality of transistor switches and the second plurality of transistor switches are silicon carbide transistor switches.

27. The power module of claim 19, further comprising:
a first busbar having first connecting lugs, by which the first busbar rests on the first electrical connection surface and is electrically connected to the first electrical connection surface;
a second busbar having second connecting lugs, by which the second busbar rests on the second electrical connection surface and is electrically connected to the second electrical connection surface; and
a third busbar having third connecting lugs, by which the third busbar rests on the respective one of the plurality of third electrical connection surfaces and is electrically connected to the respective third electrical connection surface.

28. The power module of claim 27, wherein the second and the third busbars are arranged such that they substantially overlap with one another.

29. The power module of claim 28, wherein the second connecting lugs and/or the third connecting lugs in each case run at least partially across one of the regions in each case.

30. The power module of claim 29, wherein each of the second connecting lugs and/or each of the third connecting lugs are shaped in such a manner that a space is located between the respective second connecting lugs and/or the respective third connecting lugs and the respective corresponding regions, in which space one of the snubber circuits is at least partially arranged in each case.

31. The power module of claims 19, the circuit carrier further comprising:
a first end region; and
a second end region which faces away from the first end region in the direction of extent;
wherein the first electrical connection surface and the second electrical connection surface extend along the direction of extent from the first end region up to the second end region.

32. The power module of claim 31, wherein the first electrical connection surface and the second electrical connection surface extend parallel to one another.

33. The power module of claim 19, the first electrical connection surface further comprising:
a plurality of first connection sections which extend transversely to the direction of extent and in the direction of the second electrical connection surface;
wherein the plurality of first connection sections and the plurality of third electrical connection surfaces alternate in the direction of extent.

34. The power module of one of claim 33, the circuit carrier further comprising:
a plurality of outer strip sections, which face away from one another, the first electrical connection surface and the second electrical connection surface are formed in a distributed manner on each of the plurality of outer strip sections; and
a central strip section between two of the plurality of outer strip sections, each of the plurality of third electrical connection surfaces are formed on the central strip section;
wherein the plurality of outer strip sections and the central strip section extend along the direction of extent from the first end region of the circuit carrier up to the second end region of the circuit carrier.

35. The power module of claim 34, wherein the plurality of first connection sections are formed on the central strip section.

36. The power module of one of claim 34, the second electrical connection surface further comprising:
a plurality of second connection sections which extend transversely to the direction of extent and in the direction of the first electrical connection surface;
wherein the plurality of second connection sections and the plurality of third electrical connection surfaces alternate in the direction of extent.

37. The power module of claim 36, wherein the plurality of second connection sections are formed on the central strip section.

38. The power module of claim 19, wherein the first electrical connection surface, the second electrical connection surface, the plurality of third electrical connection surfaces, and the regions of the circuit carrier are located on the same surface of the circuit carrier.

39. An inverter having:
a power module according to claim 19;
a driver circuit for operating the power module;
a housing, wherein the power module and the driver circuit are arranged in the housing.
